(19) United States
(12) Patent Application Publication
(10) Pub. No.: US 2020/0028107 A1
(43) Pub. Date: Jan. 23, 2020

(54) ORGANIC EL DEVICE

(71) Applicant: NEC LIGHTING, LTD., Tokyo (JP)

(72) Inventor: Yoshikazu SAKAGUCHI, Tokyo (JP)

(73) Assignee: NEC LIGHTING, LTD., Tokyo (JP)

(21) Appl. No.: 16/338,310

(22) PCT Filed: Jul. 13, 2017
(86) PCT No.: PCT/JP2017/025577

§ 371 Date: Mar. 29, 2019

(30) Foreign Application Priority Data
Nov. 11, 2016 (JP) 2016-220240

(51) Int. Cl. H01L 51/50; H01L 51/52; H01L 51/44

(52) U.S. Cl. CPC H01L 51/5012; H01L 51/442; H01L 51/5246

(57) ABSTRACT

The present invention provides an organic EL device that can ensure safety by automatic light emission of afterglow illumination even when the power is shut off due to a power failure, turning-off, or the like. The organic EL device (100) of the present invention includes a first substrate (110), an organic EL element part (120), and a charge storage part (130). The organic EL element part (120) and the charge storage part (130) are formed on one surface of the first substrate (110).

### TECHNICAL FIELD

The present invention relates to an organic EL device.

### BACKGROUND ART

An organic EL (Organic Electro-Luminescence) device is a self-emitting device equipped with an organic EL element (organic EL layer), which can be used, for example, as an illumination device, a light source, a display device, or the like (see, for example, Patent Literature 1).

### CITATION LIST

### Patent Literature

Patent Literature 1: WO 2011/136205 A1

### SUMMARY OF INVENTION

### Technical Problem

It is known that the organic EL device responds at a high speed, and the turning-on speed when the power is turned on is high as well as the turning-off speed when the power is turned off is high. For this reason, for example, depending on the use of the conventional organic EL device such as the illumination device or the like, it may be suddenly darkened in the event of a sudden power failure due to a disaster or the like or in the event of turning-off before bedtime, so that security cannot be ensured in some cases.

Hence, the present invention is intended to provide an organic EL device that can ensure safety by automatic light emission of afterglow illumination even when the power is shut off due to a power failure, turning-off, or the like.

### Solution to Problem

In order to achieve the above object, the present invention provides an organic EL device including: a first substrate; an organic EL element part; and a charge storage part. The organic EL element part and the charge storage part are formed on one surface of the first substrate.

### Advantageous Effects of Invention

The present invention can provide an organic EL device that can ensure safety by automatic light emission of afterglow illumination even when the power is shut off due to a power failure, turning-off, or the like.

### BRIEF DESCRIPTION OF DRAWINGS

FIGS. 1A to 1C is a plan view showing an exemplary configuration of an organic EL device according to the first example embodiment. FIG. 1A is a cross-sectional view of the organic EL device shown in FIG. 1C taken along the line A-A. FIG. 1B is a cross-sectional view of the organic EL device shown in FIG. 1C taken along the line B-B.

FIG. 2 is an equivalent circuit diagram of an example of the organic EL device according to the first example embodiment.

FIG. 3 is an equivalent circuit diagram of an example of the organic EL device according to the second example embodiment.

FIG. 4 is an equivalent circuit diagram of an example of the organic EL device according to the third example embodiment.

FIGS. 5A and 5B are cross-sectional views showing another exemplary configuration of the organic EL device according to the first example embodiment.

### DESCRIPTION OF EMBODIMENTS

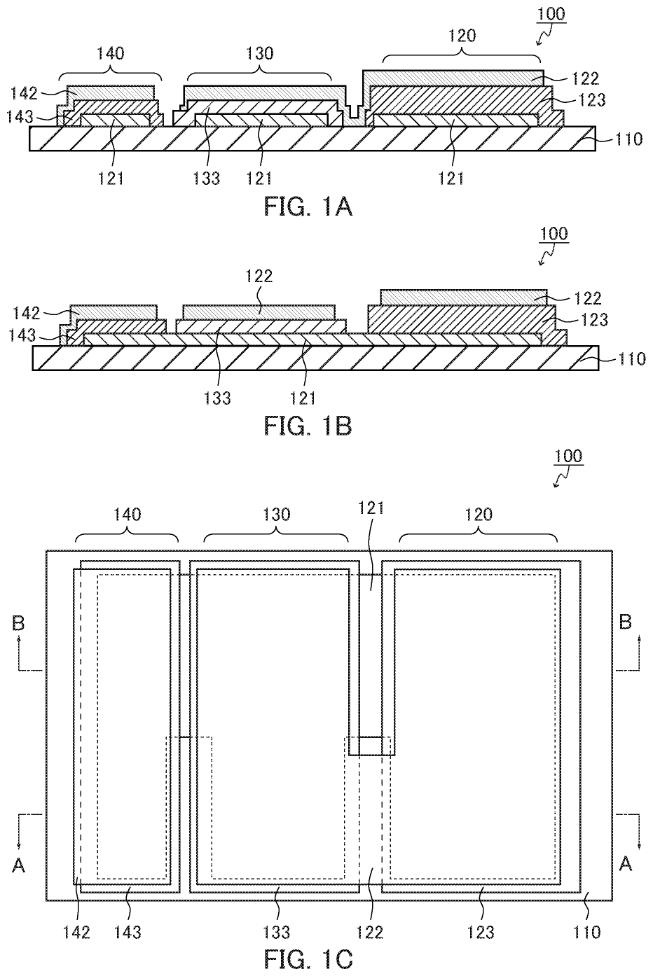

The organic EL device of the present invention is described below with reference to the drawings. It is to be noted, however, that the present invention is by no means limited or restricted by the following example embodiments. In the following FIGS. 1A to 5B, identical parts are indicated with identical reference signs. Furthermore, for convenience in explanation, the structure of each component shown in FIGS. 1A to 5B may be appropriately simplified, and the size, the ratio, and the like of components may be schematically shown and different from actual ones. Regarding the descriptions of the example embodiments, reference can be made to one another unless otherwise stated.

### First Example Embodiment

FIGS. 1A to 1C show an organic EL device of the present example embodiment. FIG. 1C is a plan view showing an exemplary configuration of the organic EL device of the present example embodiment, FIG. 1A is a cross-sectional view of the organic EL device shown in FIG. 1C taken along the line A-A, and FIG. 1B is a cross-sectional view of the organic EL device shown in FIG. 1C taken along the line B-B. As shown in FIGS. 1A to 1C, the organic EL device 100 of the present example embodiment includes a first substrate 110, an organic EL element part 120, a charge storage part 130, and a rectification part 140. The organic EL element part 120, the charge storage part 130, and the rectification part 140 are formed on one surface (the upper surface in FIGS. 1A to 1C) of the first substrate 110. In the organic EL device 100 of the present example embodiment, the rectification part 140 is optional, and the organic EL device 100 may or may not include the rectification part 140. While FIGS. 1A to 1C show the organic EL device 100 having a rectangular planar shape, the planar shape of the organic EL device is not limited to this example, and examples thereof include a polygonal shape other than a rectangular shape such as a parallelogram shape other than a rectangular shape (including a square shape and a rhombus shape), a trapezoid shape, a pentagon shape, a hexagon shape, or the like; a circular shape; an elliptical shape; and a shape close to them (for example, a substantially rectangular shape). In the present invention, as to the light emission of the organic EL element part 120, the light emission by normal energization is referred to as main illumination and the light emission by power supply from the charge storage part 130 is referred to as sub illumination or afterglow illumination.

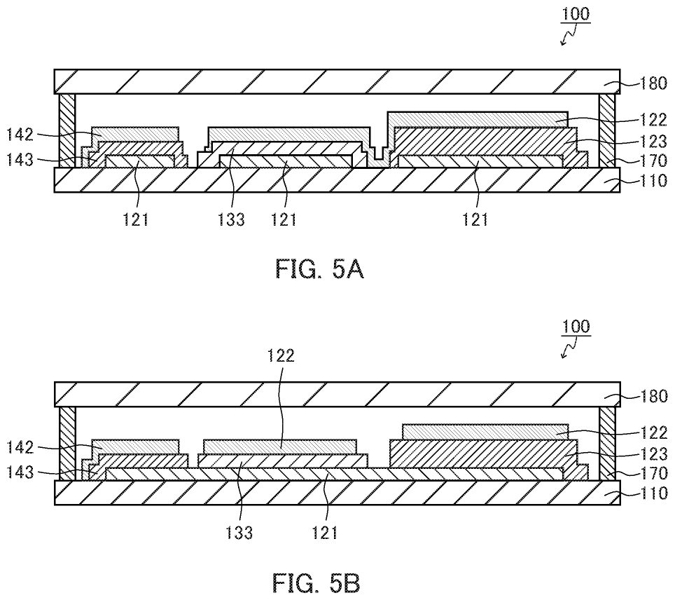

The organic EL device 100 is only required to include the first substrate 110, the organic EL element part 120, and the charge storage part 130, and other configurations are not particularly limited. The organic EL device 100 may include, for example, the first substrate 110, the organic EL element part 120, the charge storage portion 130, the rectification part 140, a seal layer 170, and a second substrate 180 as shown in FIGS. 5A and 5B. FIGS. 5A and 5B correspond to FIGS. 1A and 1B, respectively. In the example shown in FIGS. 5A and 5B, the first substrate 110 and the second substrate 180 are stacked such that one surface (the upper surface in FIGS. 5A and 5B) of the first substrate 110 and one surface (the lower surface in FIGS. 5A and 5B) of the second substrate 180 face each other with the seal layer 170 interposed therebetween. The seal layer 170 seals a gap between the first substrate 110 and the second substrate 180 over the entire end part where the first substrate 110 and the second substrate 180 face each other.

The first substrate 110 preferably has a high transmittance for transmitting light emitted from the organic EL layer 123. Examples of the material for forming the first substrate 110 include glass such as alkali-free glass, soda glass, soda lime glass, borosilicate glass, aluminosilicate glass, quartz glass, or the like; polyester such as polyethylene naphthalate, polyethylene terephthalate, or the like; polyimide; an acrylic resin such as polymethyl methacrylate, polyethyl methacrylate, polymethyl acrylate, polyethyl acrylate, or the like; polyether sulfone; and polycarbonate ester. The size (length and width) of the first substrate 110 is not particularly limited, and may be appropriately set, for example, depending on the size of a desired organic EL device 100. The thickness of the first substrate 110 is not particularly limited, and may be appropriately set depending on the forming material, the use environment, and the like, and is generally not more than 1 mm. In addition to or instead of the first substrate 110, the second substrate 180 may have a high transmittance for transmitting light emitted from the organic EL layer 123.

The organic EL element part 120 includes a pair of electrodes and an organic EL layer, and is a laminate in which one of the pair of electrodes, the organic EL layer, and the other of the pair of electrodes are stacked in this order, for example. The pair of electrodes is, for example, the combination of an anode 121 and a cathode 122, the anode 121 is, for example, a transparent electrode such as indium tin oxide (ITO), and the cathode 122 is, for example, a counter electrode such as a metal (e.g., aluminum). The organic EL layer 123 is, for example, a laminate in which a hole injection layer, a hole transport layer, a light-emitting layer including an organic EL, an electron transport layer, and an electron injection layer are sequentially stacked. The organic EL device 100 shown in FIGS. 1A to 1C and 5A and 5B is, for example, a bottom emission type organic EL device, for example. In the case of the bottom emission type organic EL device 100, for example, the organic EL element part 120 is preferably a laminate in which the transparent electrode (anode) 121, the organic EL layer 123, and the counter electrode (cathode) 122 are stacked in this order from the side of the first substrate 110. When the material for forming the second substrate 180 has a high transmittance, the anode 121 and the cathode 122 may be replaced with each other to form a top emission type organic EL device. While FIGS. 1A to 1C and 5A and 5B show an example in which one organic EL element part 120 (organic EL layer 123) is disposed on one surface of the first substrate 110, the organic EL device 100 of the present example embodiment is not limited to this example, and a plurality (two or more) of organic EL element parts (organic EL layers) may be disposed on one surface of the first substrate 110.

The second substrate 180 is a sealing substrate for shielding the organic EL element part 120 from the outside air. The second substrate 180 can be any substrate as long as the organic EL element part 120 can be shielded from the outside air, and, for example, a substrate formed of the same material as the first substrate 110 can be used. The size (length and width) of the second substrate 180 is not particularly limited, and may be appropriately adjusted so as to be substantially the same as or one size smaller than the size of the first substrate 110, for example. The thickness of the second substrate 180 is also not particularly limited, and is, for example, in the range from 0.5 mm to 1 mm.

The seal layer 170 is formed, for example, by applying an adhesive along the outer peripheral edge of one surface (the lower surface in FIGS. 5A and 5B) of the second substrate 180. The adhesive is not particularly limited, and, for example, a UV (ultraviolet) curable resin or the like can be suitably used. The seal layer 170 is formed to be slightly thicker than the thickness of the organic EL element part 120, and the thickness thereof is, for example, in the range from 0.1 μm to 100 μm.

In the organic EL device 100 of the present example embodiment, the space between the first substrate 110 and the second substrate 180 and surrounded by the seal layer 170 (the blank part in FIGS. 5A and 5B) may be filled with a filler. Examples of the filler include an inert gas and silicone. The silicone may be kneaded with a moisture catching agent such as calcium oxide.

The charge storage part 130 includes a pair of electrodes and a dielectric, and is a laminate in which one of the pair of electrodes, the dielectric, and the other of the pair of electrodes are stacked in this order, for example. The pair of electrodes is, for example, the combination of the anode 121 and the cathode 122. For example, as shown in FIGS. 1A to 1C and 5A and 5B, the charge storage part 130 may share the anode 121 and the cathode 122 with the organic EL element part 120, or the anode 121 and the cathode 122 only for the charge storage part 130 may be provided. In the case where the anode 121 and the cathode 122 only for the charge storage part 130 are provided, for example, the anode may be a transparent electrode such as ITO and the cathode may be a counter electrode such as a metal as those for the organic EL element part 120. Examples of the dielectric 133 include a thin film of metal oxide such as aluminum oxide, a thin film of inorganic oxide such as silicon oxide, a thin film of inorganic nitride such as silicon nitride, and a thin film of inorganic oxynitride such as silicon oxynitride. The material for forming the organic EL layer 123 can also serve as a dielectric having a dielectric constant, and thus may be used for forming the charge storage part 130. In this case, when an injection material for holes or electrons is used, a barrier for carriers injecting into the materials is small and the charge is less prone to be stored. Therefore, it is preferable to use a host material for a hole transport layer, a light-emitting layer, or an electron transport layer instead of the injection material for holes or electrons. Alternatively, the hole injection layer and the electron injection layer may be formed in the opposite order to that in the organic EL layer 123.

The rectification part 140 includes a pair of electrodes and an organic film, and is a laminate in which one of the pair of electrodes, the organic film, and the other of the pair of electrodes are stacked in this order, for example. The pair of electrodes is, for example, the combination of the anode 121 and the cathode 142. For example, as shown in FIGS. 1A to 1C and 5A and 5B, the rectification part 140 may share the anode 121 with the organic EL element part 120 and the charge storage part 130, or the anode 121 only for the rectification part 140 may be provided. In the case where the anode 121 only for the rectification part 140 is provided, the anode may be, for example, a transparent electrode such as ITO as that for the organic EL element part 120. The cathode 142 may be, for example, a counter electrode such as a metal as that for the organic EL element part 120. The organic film 143 is made of, for example, a unipolar material. The configuration of the organic film 143 may be the same as that of the hole transport layer or the electron transport layer in the organic EL layer 123, for example.

The method of manufacturing the organic EL device 100 of the present example embodiment is described below with reference to examples. This manufacturing method, however, is merely an example, and the organic EL device 100 of the present example embodiment may be manufactured by any method. The organic EL device 100 of the present example embodiment is preferably manufactured under an inert gas atmosphere in order to prevent the organic EL element part 120 from coming into contact with moisture.

First, the anode 121 is formed on one surface of the first substrate 110. The anode 121 can be formed through a shadow mask, for example, by forming a film with the material for forming the anode 121 by a conventionally known method such as a sputtering method, a chemical vapor deposition (CVD) method, or the like. The anode 121 can also be formed by forming a film uniformly with the material for forming the anode 121 on one surface of the first substrate 110 and patterning the film into a desired shape by photolithography.

Next, the dielectric 133 and the rectification part 140 are formed. In the manufacture of the organic EL device 100 of the present example embodiment, there is no particular limitation on the order of the formation of the organic EL element part 120, the charge storage part 130, and the rectification part 140. If the dielectric 133 and the rectification part 140 of the charge storage part 130 are formed prior to the formation of the organic EL layer 123 of the organic EL element part 120 as in the present example embodiment, the influence of the formation on the organic EL layer 123 can be eliminated.

First, the dielectric 133 is formed on the anode 121. The dielectric 133 can be formed with the material for forming the dielectric 133 by a sputtering method or the like, for example.

Next, the organic film 143 is formed on the anode 121. The organic film 143 can be formed with a conventionally known material through a shadow mask by a conventionally known method such as a vacuum deposition method by resistance heating, an MBE (Molecular Beam Epitaxy) method, a laser ablation method using, or the like. When a polymer material is used for forming the organic film 143, the organic film 143 can be formed on the anode 121 by printing such as ink-jet printing with the polymer material in a liquid state; or the organic film 143 can be formed on the anode 121 by photolithography by preparing a photosensitive coating liquid from the polymer material followed by spin coating or slit coating.

Next, the cathode 142 is formed on the organic film 143. The cathode 142 can be formed with the material for forming the cathode 142 by a conventionally known method such as a vacuum deposition method, a sputtering method, or the like, for example.

Next, the organic EL element part 120 is formed. First, the organic EL layer 123 is formed on the anode 121 in the same manner as the formation of the organic film 143 described above. Next, the cathode 122 is formed on the organic EL layer 123 in the same manner as the formation of the cathode 142 described above.

Next, the seal layer 170 is formed on the first substrate 110, the space between the first substrate 110 and the second substrate 180 and surrounded by the seal layer 170 is filled with the filler, and then the second substrate 180 is bonded or fused to the upper surface of the seal layer 170. In this manner, the organic EL device 100 of the present example embodiment can be obtained. It is to be noted that the above described steps are performed in the case where the organic EL device 100 of the present example embodiment is manufactured under an inert gas atmosphere. In the case where the inert gas is used as the filler, the space is already filled with the inert gas, so that the filling step of the filler can be omitted.

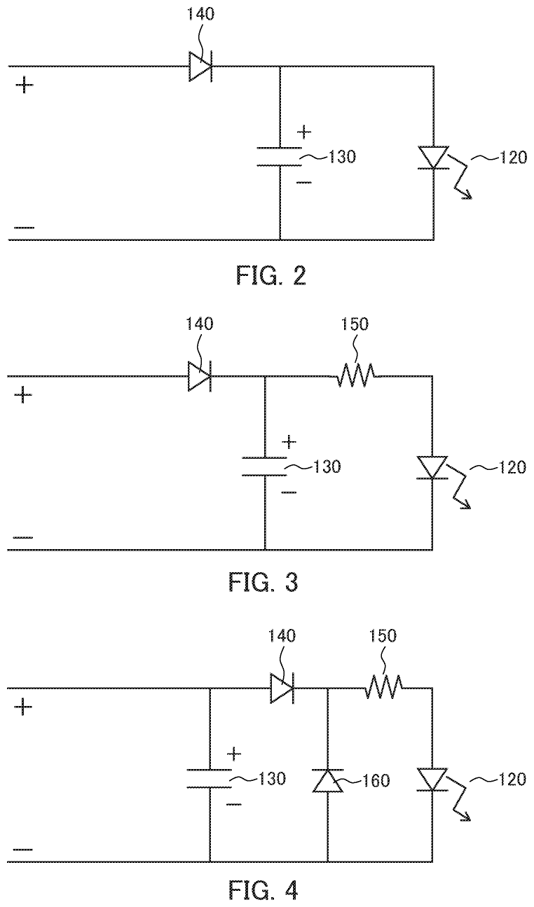

FIG. 2 is an equivalent circuit diagram of the organic EL device 100 of the present example embodiment. In FIG. 2, the “+” at the upper left and the “−” at the lower left indicate the types of electric power supplied from an external power source. The “+” indicates that the circuit is electrically connected to the anode 121 in FIGS. 1A to 1C. The “−” indicates that the circuit is electrically connected to the cathodes 122 and 142 in FIGS. 1A to 1C. According to the organic EL device 100 of the present example embodiment, electricity is stored in the charge storage part 130 when the organic EL layer 123 is turned on and emits light (main illumination).

It is to be noted, when the power is shut off due to a power failure, turning-off, or the like, the main illumination cannot be turned on. In such a case, the sub-illumination mode is switched on, and the electrical energy stored in the charge storage part 130 is supplied to the organic EL layer 123 and the organic EL layer 123 can be illuminated for a certain period of time.

As described above, by providing the charge storage part 130 that supplies the stored electrical energy to the organic EL layer 123, the organic EL device 100 of the present example embodiment can forcibly cause the organic EL layer 123 to emit light by using the stored electrical energy at the time of a power failure or turning-off, for example. In other words, automatic illumination at the time of a power failure or turning-off is also possible, so that safety can be ensured.

In addition, according to the organic EL device 100 of the present example embodiment, the charge storage part 130 and the rectification part 140 are formed at positions different from the organic EL element part 120 on one surface of the first substrate 110. Thus, for example, even when the organic EL element part 120 is formed prior to the charge storage part 130 and the rectification part 140, the influence of the formation on the organic EL layer 123 can be reduced and the degree of freedom in design can be increased.

The organic EL device 100 of the present example embodiment can be, for example, used in a wide range of applications such as illumination devices, light sources, display devices, and the like.

### Second Example Embodiment

The present example embodiment is an example of an organic EL device further including a current adjustment part that adjusts a current supplied from the charge storage part 130 to the organic EL element part 120 on one surface of the first substrate 110. FIG. 3 is an equivalent circuit diagram of the organic EL device of the present example embodiment. As shown in FIG. 3, the organic EL device of the present example embodiment is the same as the organic EL device 100 of the first example embodiment except that it further includes a current adjustment part 150 between the charge storage part 130 and the organic EL element part 120.

Examples of the current adjustment part 150 include materials having high contact resistance and materials having high resistivity such as Ta (tantalum), Cu—Ni (copper-nickel alloy), ITO, IZO (indium oxide-zinc oxide), IGZO (amorphous semiconductor composed of indium, gallium, zinc, and oxygen), and Ni—Cr (nickel-chromium alloy). The resistance value of the current adjustment part 150 can be selected and set depending on, for example, the voltage value of the external power supply, the difference of the voltage value between the external power supply and the organic EL device of the present example embodiment or the rectification part thereof, the degree of brightness of the organic EL device of the present example embodiment, and the like. As an example, when fourteen organic EL devices of the present example embodiment each including an organic EL layer driven at 6 V per layer and a rectification part of 0.6 V are connected in series using an external power source having a voltage of 100 V and driven at about 80% of the voltage of the external power source, the resistance value of the current adjustment part 150 can be, for example, in the range from 30Ω to 40Ω. Since the driving voltage of the organic EL layer gradually rises with small variation range due to continuous driving, it is preferable to drive the organic EL layer in consideration of the voltage of the external power supply.

In addition to the effect obtained in the first example embodiment, by providing the current adjustment part 150, the organic EL device of the present example embodiment can adjust and control the time for illuminating the sub illumination longer by reducing the current supplied from the charge storage part 130 to the organic EL element part 120 to increase the time constant. In addition, the current adjustment part 150 can also act to prevent a rush current from the charge storage part 130 to the organic EL element part 120 from being generated and to protect the organic EL element part 120.

### Third Example Embodiment

The present example embodiment is an example of an organic EL device further including a single-carrier unipolar element on one surface of the first substrate 110. FIG. 4 is an equivalent circuit diagram of the organic EL device of the present example embodiment. As shown in FIG. 4, the organic EL device of the present example embodiment is the same as the organic EL device of the second example embodiment except that it further includes a unipolar element 160.

The unipolar element 160 is disposed in parallel in the direction opposite to the direction of the forward bias of the organic EL element part 120, and is disposed in series in the same direction as the direction of the forward bias of the organic EL element part 120. The configuration of the unipolar element 160 is, for example, the same as that of the rectification part 140. That is, the unipolar element 160 includes a pair of electrodes and an organic film, and is a laminate in which one of the pair of electrodes, the organic film, and the other of the pair of electrodes are stacked in this order.

In addition to the effects obtained in the second example embodiment, by providing the unipolar element 160, the organic EL device of the present example embodiment achieves the following effects. That is, by setting the reverse voltage of the unipolar element 160 to be equal to or higher than the forward voltage of the organic EL element part 120, a current does not normally flow to the unipolar element 160, and therefore, the illumination of the organic EL element part 120 is not affected. On the other hand, when a large reverse bias is applied to the organic EL element part 120, a current flows to the unipolar element 160, so that the organic EL element part 120 can be prevented from being damaged. Furthermore, by disposing the unipolar element 160 whose on-voltage is adjusted in combination with the current adjustment part 150, even if a forward bias current equal to or larger than a certain value is applied to the organic EL element part 120, the current can flow to the unipolar element 160, and the organic EL element part 120 can be prevented from being damaged.

While the present invention has been described above with reference to illustrative example embodiments, the present invention is by no means limited thereto. Various changes and variations that may become apparent to those skilled in the art may be made in the configuration and specifics of the present invention without departing from the scope of the present invention.

This application claims priority from Japanese Patent Application No. 2016-220240filed on Nov. 11, 2016. The entire subject matter of the Japanese Patent Application is incorporated herein by reference.

### INDUSTRIAL APPLICABILITY

The present invention can provide an organic EL device that can ensure safety by automatic light emission of afterglow illumination even when the power is shut off due to a power failure, turning-off, or the like. The organic EL device of the present invention can be, for example, used in a wide range of applications such as illumination devices, light sources, display devices, and the like.

### REFERENCE SIGNS LIST

100 organic EL device

110 first substrate

120 organic EL element part

121 anode

122, 142 cathode

123 organic EL layer

130 charge storage part

133 dielectric

140 rectification part

143 organic film

150 current adjustment part

160 unipolar element

170 seal layer

180 second substrate

1. An organic EL device comprising:
a first substrate;
an organic EL element part; and
a charge storage part, wherein
the organic EL element part and the charge storage part are formed on one surface of the first substrate.

2. The organic EL device according to claim 1, wherein
the charge storage part comprises a pair of electrodes and a dielectric, and
the charge storage part is a laminate in which one of the pair of electrodes, the dielectric, and the other of the pair of electrodes are stacked in this order.

3. The organic EL device according to claim 1, further comprising:
a rectification part formed on one surface of the first substrate.

4. The organic EL device according to claim 3, wherein
the rectification part comprises a pair of electrodes and an organic film, and
the rectification part is a laminate in which one of the pair of electrodes, the organic film, and the other of the pair of electrodes are stacked in this order.

5. The organic EL device according to claim 1, further comprising:
a current adjustment part that adjusts a current supplied from the charge storage part to the organic EL element part on one surface of the first substrate.

6. The organic EL device according to claim 1, further comprising:
a single-carrier unipolar element on one surface of the first substrate, wherein
the unipolar element is disposed in parallel in a direction opposite to a direction of a forward bias of the organic EL element part, and is disposed in series in the same direction as the direction of the forward bias of the organic EL element part.

7. The organic EL device according to claim 1, further comprising:
a second substrate; and
a seal layer, wherein
the first substrate and the second substrate are stacked such that the one surface of the first substrate and one surface of the second substrate face each other through the seal layer, and
the seal layer seals a gap between the first substrate and the second substrate over an entire end part where the first substrate and the second substrate face each other.

8. The organic EL device according to claim 1, wherein
the organic EL element part comprises a pair of electrodes and an organic EL layer.

9. The organic EL device according to claim 8, wherein
the organic EL element part is a laminate in which one of the pair of electrodes, the organic EL layer, and the other of the pair of electrodes are stacked in this order, and the electrode on a first substrate side is a transparent electrode.

10. The organic EL device according to claim 8, wherein
the organic EL element part is a laminate in which one of the pair of electrodes, the organic EL layer, and the other of the pair of electrodes are stacked in this order, and the electrode on a second substrate side is a transparent electrode.
